(19) United States
(12) Patent Application Publication
(10) Pub. No.: US 2020/0244236 A1
(43) Pub. Date: Jul. 30, 2020

(54) ZERO VOLTAGE SWITCHING CONTROL DEVICE OF AMPLIFIER, AND WIRELESS POWER TRANSMISSION DEVICE

(71) Applicant: MAPS, INC., Yongin-si (KR)

(72) Inventors: Jong Tae HWANG, Seoul (KR); Dong Su LEE, Dongducheon-si (KR); Ki-Woong JIN, Anyang-si (KR); Min Jung KO, Seoul (KR); Hyun Ick SHIN, Seoul (KR); Joon RHEE, Seoul (KR)

(73) Assignee: MAPS, INC, Yongin-si (KR)

(21) Appl. No.: 15/759,611

(22) PCT Filed: Sep. 20, 2016
(86) PCT No.: PCT/KR2016/010473

§ 371 Date: Mar. 13, 2018

(30) Foreign Application Priority Data
Sep. 24, 2015 (KR) 10-2015-0135788

(51) Int. Cl. H03F 3/217; H03F 1/02; H03F 1/26; H02J 50/12; H02M 1/08

(52) U.S. Cl. CPC H03F 3/2176; H03F 1/0205; H03F 1/26; H03F 2200/171; H02M 1/083; H03F 2200/471; H02J 50/12

(57) ABSTRACT

Disclosed are a zero voltage switching control device of an amplifier, and a wireless power transmission device. The zero voltage switching control device, according to one embodiment of the present invention, comprises: a switch voltage detection unit which, when a first switch of an amplifier is turned on, detects a drain voltage and generates a switching voltage; an error amplification unit which receives the switching voltage as an input and amplifies an error by comparing the switching voltage with a reference voltage; a loop filter which receives an output voltage of the error amplification unit as an input, and outputs a control voltage; and a duty control unit which, according to the control voltage, controls a duty of a first switch driving signal so that the first switch undergoes zero voltage switching.

### TECHNICAL FIELD

The present invention relates to technology for a zero voltage switching control of an amplifier and a wireless power transmission.

### BACKGROUND ART

Class-E amplifiers have structures capable of generating required power with high efficiency because of satisfying a zero voltage switching (ZVS) condition basically so that the Class-E amplifiers are mainly used in wireless power transmission devices in wireless charging systems.

However, a case in which a ZVS condition is not satisfied occurs according to a load condition. Particularly, in the wireless charging system, when power consumption of a load of a receiving-end increases, the ZVS condition may not be satisfied and thus a ZVS is not performed, thereby increasing the power consumption and noise.

### DISCLOSURE

### Technical Problem

The present invention is directed to providing a zero voltage switching control device of an amplifier and a wireless power transmission device which prevent increases in power consumption and noise and perform a stable zero voltage switching.

### Technical Solution

One aspect of the present invention provides a zero voltage switching control device including a switch voltage sensor configured to detect a drain voltage of a first switch when the first switch of an amplifier is turned on and generate a switching voltage, an error amplifier configured to receive the switching voltage, compare the switching voltage with a reference voltage, and amplify an error, a loop filter configured to receive an output voltage of the error amplifier and output a control voltage, and a duty controller configured to control a duty of a driving signal of the first switch according to the control voltage and allow the first switch to be subjected to a zero voltage switching.

The duty controller may limit a minimum duty to be 50% or more.

The switch voltage sensor may include a third switch having a source connected to a first node, a drain connected to a second node, and a gate receiving a pulse signal generated from a gate driving signal of the first switch, a first diode formed between a first ground voltage and the first node, a first resistor connected to the first node and a drain of the first switch, a capacitor (Cs) formed between a second ground voltage and the second node, and a filter formed between the second node and a third ground voltage and configured to output the switching voltage.

The switch voltage sensor may detect the drain voltage of the first switch using the first switch and the first diode when the first switch is turned on, sample a first node voltage by generating the pulse signal from the gate driving signal of the first switch and turning the third switch on using the pulse signal, hold a second node voltage on the capacitor (Cs) when the third switch is turned off, and remove noise of the second node voltage using the filter to output the switching voltage.

The error amplifier may receive the switching voltage from the switch voltage sensor to compare the switching voltage with the reference voltage, output a current proportional to a voltage difference to increase the output voltage when the switching voltage is higher than the reference voltage, and receive a current proportional to a voltage difference to decrease the output voltage when the switching voltage is lower than the reference voltage.

When the drain voltage has a positive (+) value at a time at which switching of the first switch starts, the duty controller may decrease the duty as the output voltage of the error amplifier increases and the control voltage output from the loop filter increases. When the drain voltage has a negative (−) value at a time at which switching of the first switch starts, the duty controller may increase the duty as the output voltage of the error amplifier decreases and the control voltage output from the loop filter decreases.

The duty controller may delay a clock signal on the basis of the control voltage received from the loop filter, and output a gate driving voltage of the first switch using the clock signal and the delayed clock signal. Here, a maximum duty of the gate driving voltage of the first switch may be determined on the basis of a delay time of the delayed clock signal, and a minimum duty may be 50% due to the clock signal having a duty of 50%.

The zero voltage switching control device may further include a capacitance selector configured to selectively adjust a capacitance of the first switch of the amplifier.

When a zero voltage switching operation is performed with a duty of 50% or less, the capacitance selector may decrease a capacitance of a capacitor connected to the drain of the first switch of the amplifier and allow the zero voltage switching operation to be performed with a duty of 50% or more as a capacitance selection voltage is changed into a low state and a second switch of the amplifier is turned off by a low state of a capacitance selection signal.

When the drain voltage detected by detecting the drain voltage of the first switch is equal to or higher than a preset value, the capacitance selector may increase a capacitance of a capacitor connected to the drain of the first switch of the amplifier and prevent excessive generation of the drain voltage as a capacitance selection voltage is changed into a high state and a second switch of the amplifier is turned on by a high state of a capacitance selection signal.

The capacitance selector may include a D flip-flop configured to receive an inversed clock signal and a duty generation signal, determine whether the duty generation signal has a duty of 50% or less, and output a high signal to an output (Q) when the duty is 50% or less, and a set-reset (SR) latch configured to receive a high signal at an input (R) when the D flip-flop generates the high signal and allow the capacitance selection signal output from the output (Q) to be in a low state.

The capacitance selector may further include a peak detector configured to detect a drain voltage peak of the first switch in a state in which the capacitance selection signal is in a low state, and a comparator configured to output a high signal when the drain voltage peak is equal to or higher than a preset value, apply the high signal to an input S of the SR latch, allow the SR latch to output a high signal to the output (Q), and allow the capacitance selection signal output from the output (Q) to be in a high state.

Another aspect of the present invention provides a wireless power transmission device including an amplifier including a choke coil, a first switch, a first capacitor connected to a drain of the first switch, a resonance tank, and a load, and a zero voltage switching control device configured to detect a drain voltage of the first switch when the first switch is turned on, control a duty of a driving signal of the first switch to be 50% or more on the basis of a state of the detected drain voltage, and allow the first switch to perform a zero voltage switching.

The amplifier may further include a second switch and a second capacitor connected to a drain of the second switch, and the zero voltage switching control device may selectively adjust a capacitance of the first switch to prevent a zero voltage switching with a duty of 50% or less.

### Advantageous Effects

According to one embodiment of the present invention, since a duty of a switch driving signal is controlled to be 50% or more and a zero voltage switching (ZVS) is performed, problems occurring in a case in which the duty is 50% or less can be solved. For example, when the duty decreases in a case in which power consumption of a receiving-end load is high, problems in which power supplied from a power source decreases so that enough power cannot be supplied to a load and a switch is not operated with a stable duty due to a switch-on time being affected by noise during a process in which a drain voltage of the switch is detected can be solved. In addition, in a case in which the switch is driven at a high speed, a problem of difficulty to synchronize a time due to operational delay of a comparator which detects the drain voltage dropping below a specific potential can be solved.

In addition, since the duty is gradually controlled such that the drain voltage becomes 0 V at a time at which a switching starts, even when an error occurs due to noise during a process in which the drain voltage is detected, a change in duty does not suddenly occur, and thus the duty can be stably controlled. In addition, since the drain voltage is not compared by the comparator, a high speed comparator is not necessary, and thus a significantly stable operation can be performed.

### DESCRIPTION OF DRAWINGS

FIG. 1 is a configuration diagram of a general Class-E amplifier.

FIG. 2 is an operation waveform diagram of the Class-E amplifier.

FIG. 3 is an equivalent circuit diagram of the Class-E amplifier used for wireless power transmission.

FIG. 4 is a waveform diagram of a drain voltage of a switch under a light load condition.

FIG. 5 is a waveform diagram of the drain voltage of the switch under a heavy load condition.

FIG. 6 is a configuration diagram of a zero voltage switching (ZVS) control device according to one embodiment of the present invention.

FIG. 7 is a configuration diagram of a ZVS control device according to another embodiment of the present invention.

FIG. 8 is a detailed configuration diagram of a switch voltage sensor according to one embodiment of the present invention.

FIG. 9 is an operation waveform diagram of the switch voltage sensor according to one embodiment of the present invention.

FIG. 10 is an operation waveform diagram of a duty controller according to one embodiment of the present invention.

FIG. 11 is a detailed configuration diagram of the duty controller according to one embodiment of the present invention.

FIG. 12 is a detailed configuration diagram of a capacitance selector according to one embodiment of the present invention.

FIG. 13 is a waveform diagram of a result of simulating a process in which a duty is controlled and a ZVS operation is performed according to one embodiment of the present invention.

FIG. 14 is a circuit diagram of a wireless power transmission device including the Class-E amplifier according to one embodiment of the present invention and a wireless power receiving device.

FIG. 15 is a waveform diagram of a result of simulating a capacitance control in the structure of FIG. 14 according to one embodiment of the present invention.

### MODES OF THE INVENTION

Hereinafter, embodiments of the present invention will be described in detail with reference to the accompanying drawings. In the description of the present invention, when it is determined that detailed descriptions of related well-known functions or constructions may unnecessarily obscure the gist of the present invention, the detailed descriptions will be omitted. In addition, some terms described below are defined in consideration of functions in the present invention, and meanings thereof may vary depending on, for example, a user or operator's intentions or customs. Therefore, the meanings of terms should be interpreted on the basis of the scope throughout this specification.

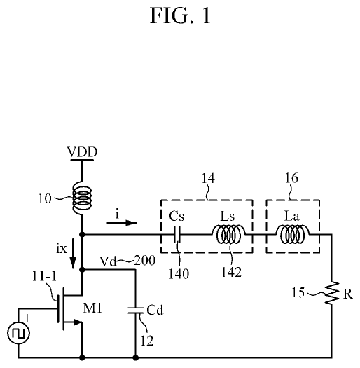

FIG. 1 is a configuration diagram of a general Class-E amplifier.

Referring to FIG. 1, the Class-E amplifier includes a choke coil 10, a first switch M1 11-1, a capacitor Cd 12 connected to a drain of the first switch M1 11-1, a resonance tank 14 having a capacitor Cs 140 and an inductor Ls 142, and a load R 15. A current flowing through the inductor Ls 142 is supplied to the load R 15. The Class-E amplifier may further include an inductor La 16 for delaying a phase of a current. The first switch M1 11-1 may be a metal-oxide semiconductor field-effect transistor (MOSFET). However, even when the first switch M1 11-1 is replaced by an active element capable of performing a switching operation, for example, a bipolar junction transistor (BJT), an SiC field effect transistor (FET), and a GaN FET, the same function as that of the first switch M1 11-1 may be performed.

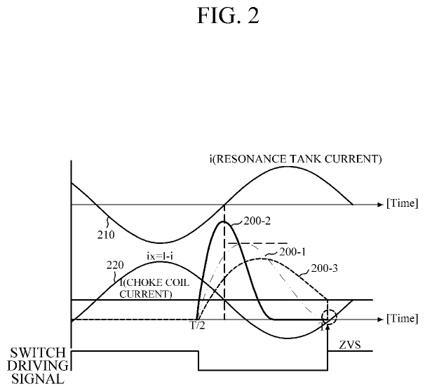

FIG. 2 is an operation waveform diagram of the Class-E amplifier.

Referring to FIGS. 1 and 2, when the first switch M1 11-1 is turned on, a drain voltage Vd 200 of the first switch M1 11-1 becomes 0 V, and a current i 210 of the resonance tank flows through the first switch M1 11-1. Here, a current ix 220, which is a current I-i, increases in a sine waveform as illustrated in FIG. 2, and even in a state in which the first switch M1 11-1 is turned off by the inductor La 16 for delaying a current phase, the current ix 220 flows in a positive (+) direction of the sine waveform. That is, the current flows toward the drain of the first switch M1 11-1 Here, since the first switch M1 11-1 is in a turned-off state, the current ix 220 charges the capacitor Cd 12, and the drain voltage Vd 200 of the first switch M1 11-1 increases in a form similar to the sine waveform as illustrated in FIG. 2. Next, as the current ix 220 decreases and a direction thereof changes, the drain voltage Vd 200 decreases gradually.

When all elements including the resonance tank 14 are properly determined, the drain voltage Vd 200 decreases to 0 V before the first switch M1 11-1 is turned on again like a first drain voltage Vd1 200-1. Here, as the first switch M1 11-1 is turned on (ON), a zero voltage switching (ZVS) may be performed. When the drain voltage Vd 200 is 0 V and the first switch M1 11-1 is turned on, since a switching loss of the first switch M1 11-1 is zero at the moment and a current which discharges the capacitor Cd 12 is not generated, electromagnetic interference (EMI) as noise is minimized.

The drain voltage Vd 200 may be changed to the first drain voltage Vd1 200-1, a second drain voltage Vd2 200-2, or a third drain voltage Vd3 200-3 according to a capacitance of the capacitor Cd 12 as illustrated in FIG. 2. The first drain voltage Vd1 200-1 is a drain voltage when the capacitor Cd 12 has a most ideal capacitance, and when the first drain voltage Vd1 200-1 is 0 V, a ZVS operation is performed.

When the capacitance of the capacitor Cd 12 is lower than the ideal capacitance, since the capacitor Cd 12 is rapidly charged, a positive gradient of the drain voltage Vd 200 increases and a negative gradient thereof also increases like the second drain voltage Vd2 200-2, and thus the drain voltage Vd 200 reaches 0 V earlier than in the case of the first drain voltage Vd1 200-1 (ZVS but high peak). Next, as a current flows through a parasitic diode between the drain and a source of the first switch M1 11-1 until the first switch M1 11-1 is turned on (ON) again, loss is additionally generated due to forward voltage drop of the diode. In addition, since a maximum value of the voltage increases, the first switch M1 11-1 may be broken down in a case in which the voltage increases higher than a peak drain operating voltage of the first switch M1 11-1.

In a case in which the capacitance of the capacitor Cd 12 increases, although a positive gradient and a peak value of the drain voltage Vd 200 decrease like the third drain voltage Vd3 200-3, since the drain voltage Vd 200 does not drop to 0 V or less before the first switch M1 11-1 is turned on again, the ZVS may not be performed (hard switching). In the state of hard switching, since charges charged in the capacitor Cd 12 are rapidly discharged by the first switch M1 11-1 when the first switch M1 11-1 is turned on again, a current having a high peak value flows through the first switch M1 11-1, and since the third drain voltage Vd3 200-3 is not 0 V, a considerable amount of power is consumed and heat is generated at the first switch M1 11-1 at the moment of switching. In addition, since a high speed and high peak current causes emission of a considerable amount of EMI, the high speed and high peak current is not desirable from a viewpoint of noise.

The Class-E amplifier may be analyzed as below. When the Class-E amplifier is in an ideal operation state, a maximum value of the drain voltage Vd 200 will be determined by Equation 1.

Vd,max=1.134×π×VDD≈3.56×VDD Equation 1

In Equation 1, VDD is a magnitude of a supply voltage of the Class-E amplifier.

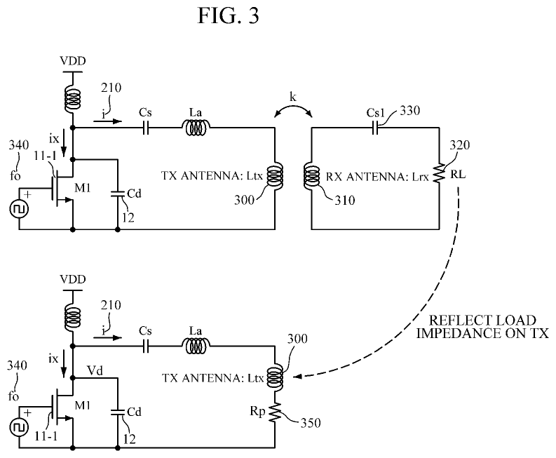

FIG. 3 is an equivalent circuit diagram of the Class-E amplifier used for wireless power transmission.

Referring to FIG. 3, current i 210 of a Class-E amplifier induces a magnetic field by a transmission antenna Ltx 300, the magnetic field induces a current at a receiving antenna Lrx 310 of a receiver, and thus energy is supplied to a load RL 320. Here, a coupling magnitude between the transmission and receiving antennas is referred as coupling coefficient k, and the coupling coefficient k may be changed from zero to 1 as a maximum value. In a case in which a resonance frequency due to the receiving antenna Lrx 310 and a capacitor Cs1 330 of the receiver is set to be the same as a driving frequency fo 340 of the Class-E amplifier, a load RL 320 may be simply equivalised to a load Rp 350 of a Class-E amplifier. Here, the load Rp 350 may be expressed as the following Equation 2.

$${R}_{p} = \frac{{( 2 π {f}_{0} \times k \sqrt{Ltx \times Lrx} )}^{2}}{RL} \qquad [ Equation 2 ]$$

According to Equation 2, since an equivalent resistance is inversely proportional to the load RL 320, in a case in which the load RL 320 decreases, that is, a large amount of power is required, the load Rp 350 increases.

A change in load affects operation of the Class-E amplifier. When the load RL 320 decreases, since the load Rp 350 increases and the current i 210 of a resonance tank decreases, the charging/discharging speed of a capacitor Cd 12 decreases, and finally, the Class-E amplifier may be in a hard switching state like the third drain voltage Vd3 200-3 of FIG. 2. Particularly, the ZVS operation may not be performed under conditions of the following Expression 3.

$${R}_{p} > \frac{8}{2 {π}^{2} {f}_{0} ( {π}^{2} + 4 ) Cd} \qquad [ Expression 3 ]$$

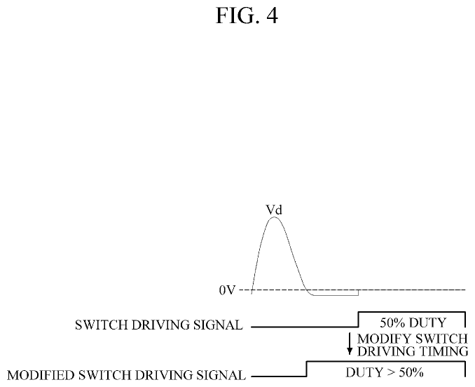

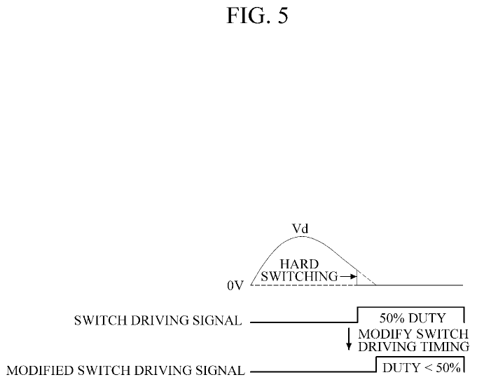

FIG. 4 is a waveform diagram of a drain voltage of a switch under a low load condition, and FIG. 5 is a waveform diagram of the drain voltage of the switch under a high load condition.

Referring to FIGS. 3, 4, and 5, in a case in which the load Rp 350 is a low load, since a general Class-E amplifier performs a switching operation with a duty of 50%, a drain voltage Vd may decrease to 0 V before a first switch M1 11-1 is turned on as illustrated in FIG. 4. Accordingly, since a current flows while a parasitic diode of the first switch M1 11-1 is turned on due to the current i of the resonance tank, the drain voltage Vd has a negative (−) value before the first switch M1 11-1 is turned on. Here, the current and a forward turn-on voltage of the diode cause additional power loss. To minimize this loss, it is preferable that the drain voltage Vd become 0 V, and at the same time, the first switch M1 11-1 be turned on through switch drive timing modification as illustrated in FIG. 4. A duty of a modified switch drive signal is 50% or more (Duty≥50%).

Meanwhile, in a case in which the load Rp 350 is a high load, the first switch M1 11-1 enters a hard switching state in which a switching is performed in a state in which the drain voltage Vd is not 0 V as illustrated in FIG. 5. Here, since charges charged in the capacitor Cd 12 are rapidly discharged when the first switch M1 11-1 is turned on, a large amount of current instantaneously flows through the first switch M1 11-1, and since the drain voltage Vd is not 0 V, instantaneous power consumption increases remarkably. This results in efficiency reduction and an increase in heat of the first switch M1 11-1. In addition, since EMI is generated due to an excessive pulse current, this may be an operational state which should be avoided the most. To avoid this phenomenon, ZVS may be performed through switch drive timing modification which delays a time at which the first switch M1 11-1 is turned on as illustrated in FIG. 5. In this case, the first switch M1 11-1 operates with a duty of 50% or less (Duty≤50%).

However, in a case in which the first switch M1 11-1 operates with a duty of 50% or less, many problems occur. For example, a status of FIG. 5 mainly occurs when power consumption of a receiving-end load is high, and when a duty is decreased, since power supplied from a power source VDD decreases, significant power may not be supplied to the load. In addition, since a switch-on time is affected by noise during a process in which the drain voltage Vd of the first switch M1 11-1 is detected, the first switch M1 11-1 may not operate with a stable duty. In a case in which the first switch M1 11-1 operates at a high speed of 6.78 MHz like alliance for wireless power (A4WP), it is difficult to turn the first switch M1 11-1 on time due to operational delay of a comparator which detects whether the drain voltage Vd drops below a specific potential. The present invention proposes a new type ZVS control technology to solve the above-described problems. Hereinafter, the new type ZVS control technology will be described with reference to the following drawings.

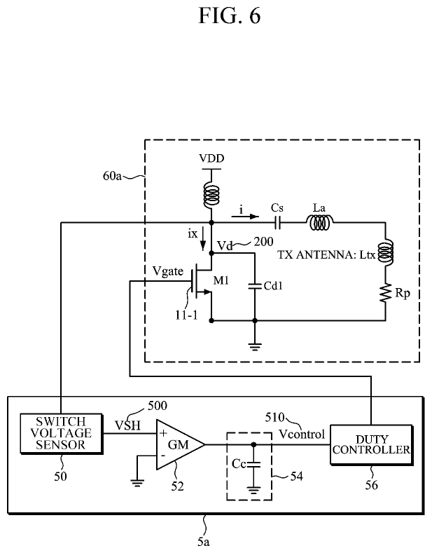

FIG. 6 is a configuration diagram of a ZVS control device according to one embodiment of the present invention.

Referring to FIG. 6, a ZVS control device 5a includes a switch voltage sensor 50, an error amplifier (amp) 52, a loop filter 54, and a duty controller 56.

The switch voltage sensor 50 detects an output voltage of a first switch M1 11-1 at a time at which the first switch M1 11-1 of a Class-E amplifier 60a is turned on and maintains the output voltage. Accordingly, whenever a switching starts, the switch voltage sensor 50 detects a drain voltage Vd 200 and generates a switching voltage VSH 500.

The error amp 52 receives the switching voltage VSH 500 from the switch voltage sensor 50, compares the switching voltage VSH 500 with a reference voltage, and amplifies an error. Here, the reference voltage may be 0 V. In a case in which the switching voltage VSH 500 is higher than 0 V, an output of the error amp 52 increases, and in the reverse case, the output of the error amp 52 decreases.

The error amp 52 according to one embodiment is a transconductance amp which converts a difference in input voltage into a current. Accordingly, when the difference in input voltage has a positive (+) value, the error amp 52 outputs a current proportional to the voltage difference, and when the difference in input voltage has a negative (−) value, the error amp 52 receives a current proportional to the voltage difference. Due to such an operation, a capacitance of a capacitor Cc of the loop filter 54 gradually decreases or increases. The loop filter 54 outputs a control voltage Vcontrol 510 and applies the control voltage Vcontrol 510 to the duty controller 56.

When the received control voltage Vcontrol 510 is high, the duty controller 56 decreases a duty of a driving signal of the first switch M1 11-1, and conversely, when the control voltage Vcontrol 510 is low, the duty controller 56 increases the duty. Accordingly, in a case in which the drain voltage Vd 200 has a positive (+) value at a moment of switching, the duty decreases gradually, and in a case in which the drain voltage Vd 200 has a negative (−) value, the duty increases gradually. Here, a maximum duty may be set to a value less than a predetermined value, and a minimum duty may be limited to 50%.

The error amp 52 may be the transconductance amp as illustrated in FIG. 6, and may be an operational amp (Op amp) instead of the transconductance amp. However, in this case, a configuration of the loop filter 54 may be different from that of FIG. 6.

When the circuit of FIG. 6 operates in a steady state, an input voltage of both ends of the error amp 52 becomes 0 V. That is, the duty is gradually controlled such that the drain voltage Vd 200 becomes 0 V at a time at which the switching starts. Accordingly, although a ZVS operation may not be performed when the circuit is in a transient-state, the circuit enters a steady state as time passes, and from this time, the ZVS operation may be successfully performed. Accordingly, when an error occurs due to noise during a process in which the drain voltage Vd 200 is detected but the error occur infrequently, since a change in duty does not occurs rapidly, the duty may be stably controlled. In addition, since the drain voltage Vd 200 is not compared by a comparator, a high speed comparator is not necessary, and a stable operation may be performed even with a very low speed error amp 52.

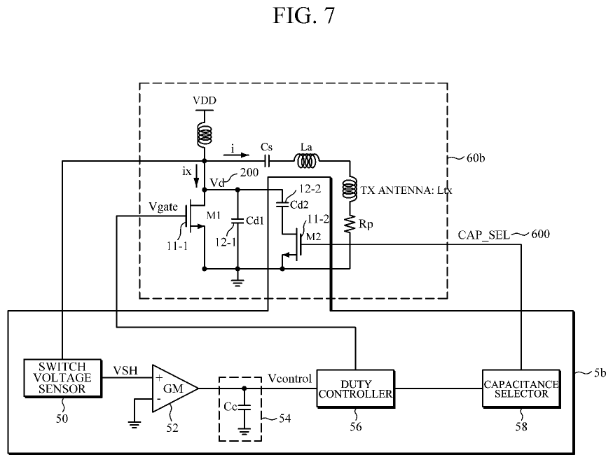

FIG. 7 is a configuration diagram of a ZVS control device according to another embodiment of the present invention.

When a ZVS control device 5b of FIG. 7 is compared with the ZVS control device 5a of FIG. 6, the ZVS control device 5b of FIG. 7 further includes a capacitance selector 58 when compared with the ZVS control device 5a of FIG. 6, and a Class-E amplifier 60b of FIG. 7 further includes a second capacitor Cd2 12-2 and a second switch M2 11-2 when compared with the Class-E amplifier 60a of FIG. 6.

The reason why a minimum duty is limited to 50% in the present invention is that, when the duty is 50% or less, although a ZVS condition may be satisfied, power required by a load may not be supplied. However, when the duty is not allowed to be 50% or less, since a status in which the ZVS operation may not be performed may occur, the ZVS control device 5b additionally includes the capacitance selector 58 as illustrated in FIG. 7.

Referring to FIG. 7, the second switch M2 11-2 of the Class-E amplifier 60b generally operates in an on-state. Accordingly, a total capacitance of a first capacitor Cd1 12-1 and the second capacitor Cd2 12-2 respectively connected to a first switch M1 11-1 and the second switch M2 11-2 is summing of a capacitance of the first capacitor Cd1 and a capacitance of the second capacitor Cd2. During an operation in this state, if the ZVS condition is satisfied only when the duty is 50% or less , the capacitance selector 58 determines such a state, changes a capacitance selection signal CAP_SEL 600 into a low state, and turns the second switch M2 11-2 off. Here, the total capacitance is the capacitance of the first capacitor Cd1, and a change speed of the drain voltage Vd 200 becomes fast. Accordingly, the ZVS condition may be satisfied in 50% or more duty condition without sacrificing power delivery capability. However, even in this state, the duty controller 56 operates such that the duty increases in a case in which a duty of 50% or more is required, and the ZVS operation is completed.

In this state, when the load decreases, the drain voltage Vd 200 may decrease and the duty controller 56 may increase the duty as illustrated in FIG. 4. In a case in which the drain voltage Vd 200 excessively increases, although the ZVS condition may be satisfied, the first switch M1 11-1 may be broken down. Accordingly, the capacitance selector 58 determines a case in which the drain voltage Vd 200 is excessive, turns the second switch M2 11-2, which has been turned off, on, and increases the capacitance to the capacitance of the first capacitor Cd1 and the second capacitor Cd2 again.

Since the ZVS condition is satisfied under various load conditions through a series of the above-described operations and a maximum duty does not decrease to 50% or less, there is no problem of power supply to the load. Although there is a demerit in that the second switch M2 11-2 is additionally necessary, since cost of a switch has been very cheap, the additional second switch M2 11-2 may be readily acceptable in consideration of safety of a system.

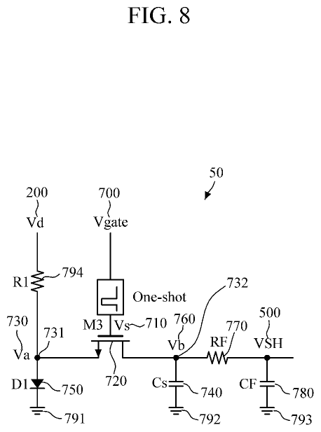

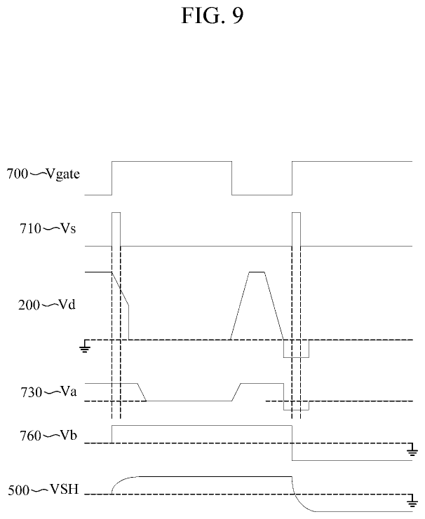

FIG. 8 is a detailed configuration diagram of a switch voltage sensor according to one embodiment of the present invention, and FIG. 9 is an operation waveform diagram of the switch voltage sensor according to one embodiment of the present invention.

Hereinafter, a structure of the switch voltage sensor 50 will be described. Referring to FIGS. 7, 8, and 9, the switch voltage sensor 50 includes a third switch M3 720, a first node 731, a second node 732, a capacitor Cs 740, a first diode D1 750, a filter having a resistor RF 770 and a capacitor CF 780, a first ground voltage 791, a second ground voltage 792, a third ground voltage 793, and a first resistor R1 794.

In the third switch M3 720, a source is connected to the first node 731, a drain is connected to the second node 732, and a pulse signal Vs 710 generated from a gate driving signal Vgate 700 of the first switch M1 11-1 is applied to a gate. A first node voltage Va 730 is applied to the first node 731, and a second node voltage Vb 760 is applied to the second node 732. The first diode D1 750 is formed between the first ground voltage 791 and the first node 731. The first resistor R1 794 is connected to the first node 731 and the drain of the first switch M1 11-1. The capacitor Cs 740 is formed between the second ground voltage 792 and the second node 732. The resistor RF 770 and the capacitor CF 780 of the filter are formed between the second node 732 and the third ground voltage 793 and output a switching voltage VSH.

Hereinafter, operation of the switch voltage sensor 50 will be described. A short pulse signal Vs 710 the same as the pulse signal Vs 710 of FIG. 9 is generated using a one-shot circuit at an ascending edge of the gate driving signal Vgate 700 of the first switch M1 11-1. The pulse signal Vs 710 turns the third switch M3 720 on and samples the first node voltage Va 730, and when the third switch M3 720 is turned off, the second node voltage Vb 740 is held on the capacitor Cs 740. Accordingly, the third switch M3 720 and the capacitor Cs 740 serve to perform a sample and hold function.

The drain voltage Vd 200 is detected using the first switch M1 11-1 and the first diode D1 750. In the present invention, since a magnitude of the drain voltage Vd 200 of the first switch M1 11-1 is not important and only positive (+), negative (−), and zero values thereof are important, even when the voltage is clamped using the first diode D1 750, there is no problem in the operation. When the first diode D1 750 is used, since voltage swing of the first node voltage Va 730 is limited to a turn-on voltage of the diode, a fast operation may be performed.

A smooth signal of the switching voltage VSH 500 from which noise is removed is generated from the sampled and held second node voltage Vb 760 by the resistor RF 770 and the capacitor CF 780 of the filter. The error amp 52 compares the switching voltage VSH 500 with 0 V which is the reference voltage and uses the comparison result to control the duty.

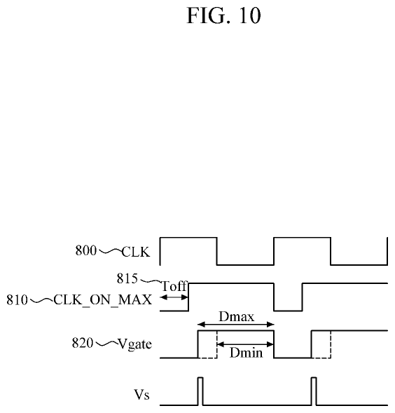

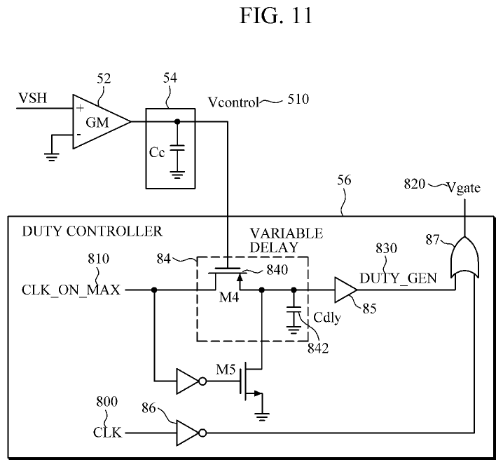

FIG. 10 is an operation waveform diagram of a duty controller according to one embodiment of the present invention, and FIG. 11 is a detailed configuration diagram of the duty controller according to one embodiment of the present invention.

Referring to FIGS. 10 and 11, a variable delay circuit 84 of the duty controller 56 delays a CLK_ON_MAX signal 810 on the basis of the control voltage Vcontrol 510 input from the loop filter 54. The variable delay circuit 84 according to one embodiment includes a fourth switch M4 840 and a capacitor Cdly 842. A logic circuit 85 receives the delayed CLK_ON_MAX signal 810 to generate a duty generation signal DUTY_GEN 830. An OR block 87 receives the duty generation signal DUTY_GEN 830 and a CLK signal inverted by an inverter 86 to output a gate driving voltage Vgate 820 through an OR operation.

The duty controller 56 according to one embodiment outputs the gate driving voltage Vgate 820 using a clock signal CLK 800 with a duty of 50% and the CLK_ON_MAX signal 810 which is delayed from the clock signal CLK 800 by a delay time Toff 815. The CLK_ON_MAX signal 810 is used as a signal for determining a maximum duty.

The fourth switch M4 840 of the duty controller 56 is a p-channel metal-oxide-semiconductor (PMOS) transistor and is used as a variable resistor. For example, when a gate signal of the fourth switch M4 840 increases, the resistance thereof increases, and conversely, as the gate signal approaches 0 V, the resistance has a minimum value. The variable resistor and the capacitor Cdly 842 delay the CLK_ON_MAX signal 810. Since the gate signal of the fourth switch M4 840 relates to the control voltage Vcontrol which is an output signal of the error amp 52, the delay is changed on the basis of the output voltage of the error amp 52. Accordingly, when the control voltage Vcontrol increases, the duty decreases. Then, the OR block 87 receives the duty generation signal DUTY_GEN 830 generated by the logic circuit 85 and the CLK signal inverted by the inverter 86 and outputs the gate driving voltage Vgate 820 though the OR operation. Accordingly, the duty is generated by the duty controller 56, wherein the duty is changed from the maximum duty which is the same as that of the CLK_ON_MAX signal 810 to the minimum duty of 50%. Since the maximum duty is determined by the delay time Toff 815, the maximum duty is calculated as T−Toff/T×100%, wherein T is one period.

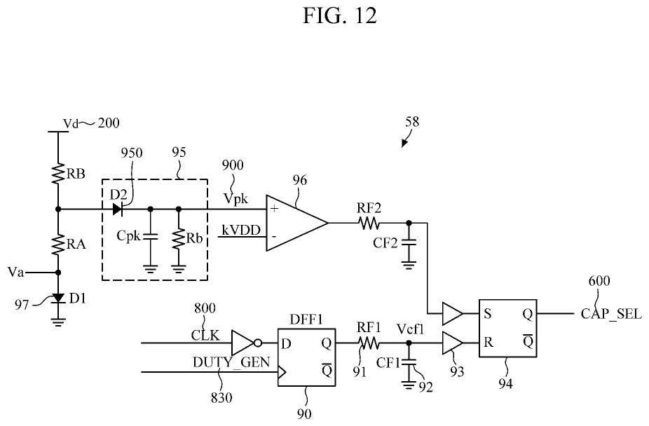

FIG. 12 is a detailed configuration diagram of a capacitance selector according to one embodiment of the present invention.

Referring to FIGS. 7 and 12, a D flip-flop DFF1 90 of the capacitance selector 58 receives the inverted clock signal CLK 800 and the duty generation signal DUTY_GEN 830 and determines whether a duty of the duty generation signal DUTY_GEN 830 is 50% or less. When the duty is 50% or less, the ZVS operation is not performed with the duty of 50%. In this state, the D flip-flop DFF1 90 outputs a high signal to an output Q and charges a capacitor CF1 92 through a resistor RF1 91 connected to the output Q. When a voltage Vcf1 of the capacitor CF1 92 becomes higher than a threshold value of a buffer 93 connected to the capacitor CF1 92, a high signal is input to an input (reset) R of a set-reset (SR) latch 94 and a capacitance selection signal CAP_SEL 600 output from the output Q becomes a low state. The second switch M2 11-2 is turned off by the capacitance selection signal CAP_SEL 600 in the low state. Accordingly, a capacitance of the first switch M1 11-1 of the Class-E amplifier 60b decreases to the capacitance of the capacitor Cd1 connected to the drain of the first switch M1 11-1. Since the capacitance decreases, a charging/discharging speed of the first switch M1 11-1 increases, and thus the ZVS condition is satisfied.

Meanwhile, when power consumption of the load decreases in the low state of the capacitance selection signal CAP_SEL, a peak value of the drain voltage of the first switch M1 11-1 increases as illustrated in FIG. 4. In a case in which the peak value increases excessively, since the first switch M1 11-1 may be broken down, the drain voltage Vd 200 is detected using a peak detector 95 as illustrated in FIG. 12. Here, a voltage Vpk 900 is calculated by Equation 4.

$$Vpk = \frac{RA}{RA + RB} Vd , p k \qquad [ Equation 4 ]$$

In Equation 4, Vd,pk is a peak voltage of the drain voltage Vd.

When the voltage Vpk 900 is higher than k×VDD, a comparator 96 outputs a high signal, the high signal is input to an input S of the SR latch 94, and a high signal is output to an output Q of the SR latch 94. The capacitance selection signal CAP_SEL becomes a high state due to the high signal of the output Q, the second switch M2 11-2 is turned on again, and the capacitance of the drain of the first switch M1 11-1 increases to the capacitance of the first capacitor Cd1 and the second capacitor Cd2. Since the capacitance has increased, the charging/discharging speed decreases, and thus the peak voltage decreases. Here, the Vd,pk voltage by which a high signal is output from the comparator 96 is expressed as the following Expression 5.

$$Vd , p k > k ( 1 + \frac{RB}{RA} ) VDD \qquad [ Expression 5 ]$$

When a Class-E amplifier operates normally, since a relational expression between the Vd,pk and the VDD is as shown in Equation 1, k, RA, and RB may be set to meet the following Expression 6.

$$k ( 1 + \frac{RB}{RA} ) > 3.56 \qquad [ Expression 6 ]$$

A diode D1 97 of the capacitance selector 58 compensates a voltage drop due to a diode D2 950. In addition, a voltage of the diode D1 97 may be used as a voltage Va needed by the switch voltage sensor 50.

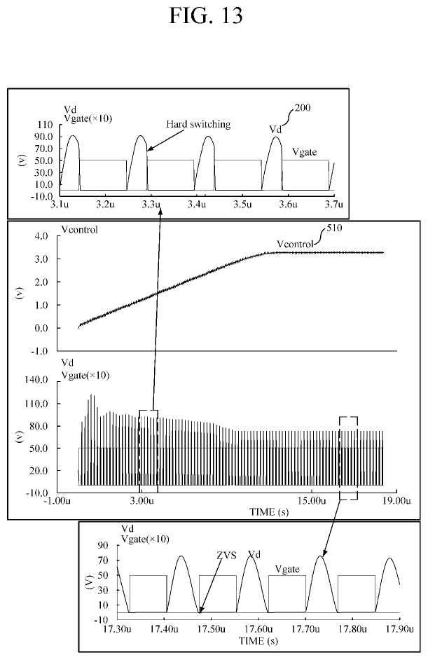

FIG. 13 is a waveform diagram of a result of simulating a process in which a duty is controlled and a ZVS operation is performed according to one embodiment of the present invention.

Referring to FIGS. 7 and 13, in an initial state of the Class-E amplifier, a hard switching operation is performed, wherein the switching is performed in a state in which the drain voltage Vd 200 of the first switch M1 is high. Accordingly, the control voltage Vcontrol 510, which is an output of the error amp 52, increases gradually, and this means that the duty should be decreased. Next, after a time period of about 10 μs passes, the duty is successfully controlled and the ZVS operation is performed. Although there is a demerit in that the ZVS operation is not performed immediately when the hard switching is performed, the circuit is resistant to noise due to completion of the ZVS operation in a relatively short time period and the operations of the error amp 52 and the loop filter 54. That is, when the Class-E amplifier enters in a normal state, the duty due to noise is not sensitively changed.

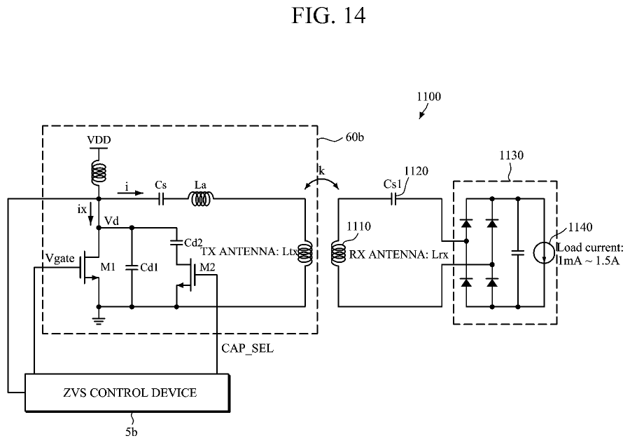

FIG. 14 is a circuit diagram of a wireless power transmission device including the Class-E amplifier according to one embodiment of the present invention and a wireless power receiving device.

Referring to FIG. 14, a wireless power transmission device includes the Class-E amplifier 60b and the ZVS control device 5b. A wireless power receiving device 1100 includes a wireless power receiving circuit 1130 connected to a RX antenna 1110. The RX antenna 1110 of the wireless power receiving device 1100 and a capacitor Cs1 1120 forms a resonance tank, and a driving frequency of the wireless power transmission device becomes the same as a resonance frequency. Four diodes of the wireless power receiving circuit 1130 serve as a rectifier which converts an AC signal received from the RX antenna 1110 into a DC signal. An output of the rectifier is connected to a current source 1140 which determines a load current.

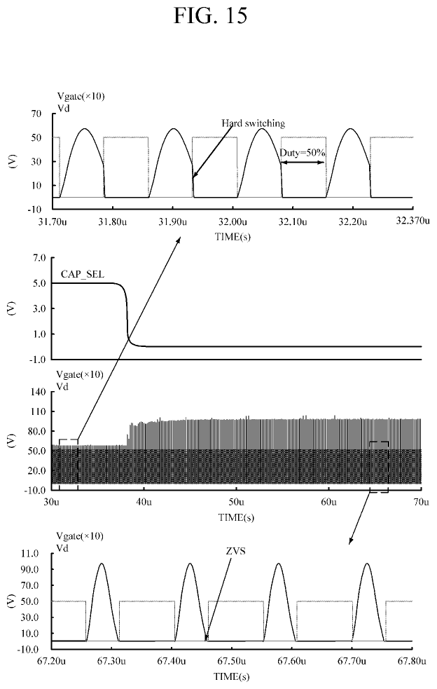

FIG. 15 is a waveform diagram of a result of simulating a capacitance control in the structure of FIG. 14 according to one embodiment of the present invention.

Referring to FIGS. 14 and 15, when the load current is set to 1.5 A, although a duty has been controlled to reach the minimum duty of 50%, the hard switching is still performed. It may be seen that, after such a condition is detected and a predetermined time period passes, the capacitance selection signal CAP_SEL becomes a low state, and the ZVS operation is finally performed due to the duty control operation.

While this inventive concept has been particularly shown and described with reference to exemplary embodiments thereof, it will be understood by those skilled in the art that various changes in form and details may be made therein without departing from the spirit and scope of the present invention as defined by the appended claims. The exemplary embodiments should be considered in a descriptive sense only and not for purposes of limitation. Therefore, the scope of the present invention is defined not by the detailed description of embodiments but by the appended claims, and all differences within the scope will be construed as being included in the inventive concept.

1. A zero voltage switching control device comprising:
a switch voltage sensor configured to detect a drain voltage of a first switch when the first switch of an amplifier is turned on and generate a switching voltage;
an error amplifier configured to receive the switching voltage, compare the switching voltage with a reference voltage, and amplify an error;
a loop filter configured to receive an output voltage of the error amplifier and output a control voltage; and
a duty controller configured to control a duty of a driving signal of the first switch according to the control voltage and allow the first switch to perform a zero voltage switching.

2. The zero voltage switching control device of the claim 1, wherein the duty controller limits a minimum duty to be 50% or more.

3. The zero voltage switching control device of the claim 1, wherein the switch voltage sensor includes:
a third switch having a source connected to a first node, a drain connected to a second node, and a gate receiving a pulse signal generated from a gate driving signal of the first switch;
a first diode formed between a first ground voltage and the first node;
a first resistor connected to the first node and a drain of the first switch;
a capacitor (Cs) formed between a second ground voltage and the second node; and
a filter formed between the second node and a third ground voltage and configured to output the switching voltage.

4. The zero voltage switching control device of the claim 3, wherein the switch voltage sensor:
detects the drain voltage of the first switch using the first switch and the first diode when the first switch is turned on;
samples a first node voltage by generating the pulse signal from the gate driving signal of the first switch and turning the third switch on using the pulse signal;
holds a second node voltage on the capacitor (Cs) when the third switch is turned off; and
removes noise of the second node voltage using the filter to output the switching voltage.

5. The zero voltage switching control device of the claim 1, wherein the error amplifier:
receives the switching voltage from the switch voltage sensor to compare the switching voltage with the reference voltage;
outputs a current proportional to a voltage difference to increase the output voltage when the switching voltage is higher than the reference voltage; and
receives a current proportional to a voltage difference to decrease the output voltage when the switching voltage is lower than the reference voltage.

6. The zero voltage switching control device of the claim 1, wherein, when the drain voltage has a positive (+) value at a time at which switching of the first switch starts, the duty controller decreases the duty as the output voltage of the error amplifier increases and the control voltage output from the loop filter increases.

7. The zero voltage switching control device of the claim 1, wherein, when the drain voltage has a negative (−) value at a time at which switching of the first switch starts, the duty controller increases the duty as the output voltage of the error amplifier decreases and the control voltage output from the loop filter decreases.

8. The zero voltage switching control device of the claim 1, wherein the duty controller:
delays a clock signal on the basis of the control voltage received from the loop filter; and
outputs a gate driving voltage of the first switch using the clock signal and the delayed clock signal.

9. The zero voltage switching control device of the claim 8, wherein:
a maximum duty of the gate driving voltage of the first switch is determined on the basis of a delay time of the delayed clock signal; and
a minimum duty is 50% due to the clock signal having a duty of 50%.

10. The zero voltage switching control device of the claim 1, further comprising a capacitance selector configured to selectively adjust capacitance of the first switch of the amplifier.

11. The zero voltage switching control device of the claim 10, wherein, when a zero voltage switching operation is performed with a duty of 50% or less, the capacitance selector decreases a capacitance of a capacitor connected to a drain of the first switch of the amplifier and allows the zero voltage switching operation to be performed with a duty of 50% or more as a capacitance selection voltage is changed into a low state and a second switch of the amplifier is turned off by a low state of a capacitance selection signal.

12. The zero voltage switching control device of the claim 10, wherein, when the drain voltage detected by detecting the drain voltage of the first switch is equal to or higher than a preset value, the capacitance selector increases a capacitance of a capacitor connected to a drain of the first switch of the amplifier and prevents excessive generation of the drain voltage as a capacitance selection voltage is changed into a high state and a second switch of the amplifier is turned on by a high state of a capacitance selection signal.

13. The zero voltage switching control device of the claim 10, wherein the capacitance selector includes:
a D flip-flop configured to receive an inversed clock signal and a duty generation signal, determine whether the duty generation signal has a duty of 50% or less, and output a high signal to an output (Q) when the duty is 50% or less; and
a set-reset (SR) latch which has an input (R) configured to receive a high signal when the D flip-flop generates the high signal and allows a capacitance selection signal output from an output (Q) to be in a low state.

14. The zero voltage switching control device of the claim 13, wherein the capacitance selector further includes:
a peak detector configured to detect a drain voltage peak of the first switch in a state in which the capacitance selection signal is in a low state; and
a comparator configured to output a high signal when the drain voltage peak is equal to or higher than a preset value, apply the high signal to an input S of the SR latch, allow the SR latch to output a high signal to the output (Q), and allow the capacitance selection signal output from an output (Q) to be in a high state.

15. A wireless power transmission device comprising:
an amplifier including a choke coil, a first switch, a first capacitor connected to a drain of the first switch, a resonance tank, and a load; and
a zero voltage switching control device configured to detect a drain voltage of the first switch when the first switch is turned on, control a duty of a driving signal of the first switch to be 50% or more on the basis of a state of the detected drain voltage, and allow the first switch to perform a zero voltage switching.

16. The wireless power transmission device of claim 15, wherein:
the amplifier further includes a second switch and a second capacitor connected to a drain of the second switch; and
the zero voltage switching control device selectively adjusts a capacitance of the first switch to prevent a zero voltage switching with a duty of 50% or less.
